(19) United States
(12) Patent Application Publication
(10) Pub. No.: US 2011/0165320 A1
(43) Pub. Date: Jul. 7, 2011

(54) DEPOSITION SOURCE, THIN FILM DEPOSITION APPARATUS AND METHOD OF MANUFACTURING ORGANIC LIGHT-EMITTING DISPLAY APPARATUS

(75) Inventors: Yong-Sup CHOI, Yongin-city (KR); Hee-Cheol Kang, Yongin-city (KR); Young-Mook Choi, Yongin-city (KR); Jong-Heon Kim, Yongin-city (KR); Jae-Kwang Ryu, Yongin-city (KR)

(73) Assignee: Samsung Mobile Display Co., Ltd., Yongin-city (KR)

(21) Appl. No.: 12/820,355

(22) Filed: Jun. 22, 2010

(30) Foreign Application Priority Data
Jan. 6, 2010 (KR) 10-2010-0000897

(51) Int. Cl. B05D 5/06; C23C 16/00; C23C 16/44

(52) U.S. Cl. 427/66; 118/726

(57) ABSTRACT

A deposition source, a thin film deposition apparatus, and a method of manufacturing an organic light-emitting display apparatus, the deposition source including: a crucible to hold a deposition material; a heater to heat the deposition material; a nozzle unit disposed at a side of the crucible; a first connector disposed between the crucible and the nozzle unit; a first valve disposed on the first connector to control the flow of the deposition material to the nozzle unit; a deposition material recovery unit to collect the deposition material; a second connector to connect the first connector to the deposition material recovery unit; and a second valve to control the flow of the deposition material through the second connector.

### CROSS-REFERENCE TO RELATED APPLICATION

This application claims the benefit of Korean Patent Application No. 10-2010-0000897, filed on Jan. 6, 2010, in the Korean Intellectual Property Office, the disclosure of which is incorporated herein by reference.

### BACKGROUND

1. Field

The present disclosure relates to a deposition source, a thin film deposition apparatus, and a method of manufacturing an organic light-emitting display apparatus, and method of using the same.

2. Description of the Related Art

Organic light-emitting display devices have a larger viewing angle, better contrast characteristics, and a faster response rate than other display devices. Thus, such devices have drawn attention as the next-generation of display device.

Organic light-emitting display devices generally have a stacked structure, including an anode, a cathode, and an emission layer interposed between the anode and the cathode. The devices generally emit light when holes and electrons, injected respectively from an anode and a cathode, recombine in an emission layer. To improve light-emission efficiency, organic light-emitting layers and organic layers, including an electron injection layer, an electron transport layer, a hole transport layer, a hole injection layer, etc., are optionally interposed between the emission layer and each of the electrodes.

The electrodes, the organic light-emitting layers, and the organic layers may be formed via various methods, such as a deposition method. When an organic light-emitting display device is manufactured using the deposition method, a deposition material contained in a crucible is heated, vaporized, and then is moved to a target, such as a substrate, upon which the deposition material is to be deposited.

At certain times during the deposition process, the deposition material is not substantially deposited on a target, even though the deposition material is vaporized. For example, when another target is aligned relative to a deposition apparatus, the deposition material does not need to be heated and vaporized. However, the deposition material may continue to be vaporized during the alignment, without operating a heater of the deposition apparatus. Thus, the deposition material may be wasted or denatured.

Display devices are currently being produced in ever increasing sizes. However, in conventional thin film deposition apparatuses, it is difficult to form organic deposition layers having desired characteristics, on a large area. Thus, there is a limitation in improving characteristics of the devices, using current methods.

### SUMMARY

The present disclosure provides a deposition source that may prevent denaturation of deposited materials and may easily improve the characteristic of a deposited thin layer. The present disclosure also provides a thin film deposition apparatus including the deposition source, and a method of manufacturing an organic light-emitting display apparatus using the same.

According to an aspect of the present disclosure, there is provided a deposition source. The deposition source includes: a crucible to hold a deposition material; a heater to heat the deposition material; a nozzle unit to eject the deposition material; a first connector providing a fluid communication between the crucible and the nozzle unit; a first valve to control the flow of the deposition material through the first connector; a deposition material recovery unit to collect the deposition material; a second connector providing a fluid communication between the first connector and the deposition material recovery unit; and a second valve to control the flow of the deposition material through the second connector.

According to various embodiments, the second connector may be disposed in the first connector, between the crucible and the first valve, and the second valve may be disposed in the second connector.

According to various embodiments, the deposition source may further include a cooling member disposed around the crucible.

According to various embodiments, the cooling member may be separated from the heater.

According to various embodiments, the deposition material recovery unit may include a detachable recovery plate, on which the collected deposition material is stacked.

According to various embodiments, the deposition material recovery unit may recover the deposition material when the first valve has been closed and the second valve has been opened.

According to various embodiments, the nozzle unit may include a plurality of nozzles.

According to an aspect of the present disclosure, there is provided a thin film deposition apparatus. The thin film deposition apparatus includes: a crucible to hold a deposition material; a heater to heat the deposition material; a nozzle unit to eject the deposition material; a first connector providing a fluid communication between the crucible and the nozzle unit; a first valve disposed on the first connector, to control the flow of the deposition material through the first connector; a deposition material recovery unit to collect the deposition material; a second connector providing a fluid communication between the first connector and the deposition material recovery unit; a second valve to control the flow of the deposition material through the second connector; a patterning slit sheet disposed opposite to the nozzle unit and including a plurality of patterning slits arranged in the first direction; and a barrier wall assembly. The barrier wall assembly includes barrier walls disposed between the nozzle unit and the patterning slit sheet, which are spaced apart in a first direction, to partition a space between the nozzle unit and the patterning slit sheet into a plurality of sub-deposition spaces.

According to various embodiments, the second connector may be attached to the first connector, between the crucible and the first valve, and the second valve may be disposed in the second connector.

According to various embodiments, the thin film deposition apparatus may further include a cooling member surrounding the crucible.

According to various embodiments, the cooling member may be separated from the heater.

According to various embodiments, the deposition material recovery unit may include a detachable recovery plate, on which the collected deposition material is stacked.

According to various embodiments, the deposition material recovery unit may recover the deposition material when the first valve has been closed and the second valve has been opened.

According to various embodiments, the barrier walls may be separated from the patterning slit sheet.

According to various embodiments, the barrier walls may be arranged at equal intervals.

According to various embodiments, the deposition source and the barrier wall assembly may be separated from each other.

According to various embodiments, the barrier wall assembly may include a first barrier wall assembly including a plurality of first barrier walls, and a second barrier wall assembly including a plurality of second barrier walls.

According to various embodiments, each of the first barrier walls and each of the second barrier walls may extend in a second direction that is substantially perpendicular to the first direction, in order to partition the space between the nozzle unit and the patterning slit sheet into the plurality of sub-deposition spaces.

According to various embodiments, the first barrier walls may be arranged to respectively correspond to the second barrier walls.

According to various embodiments, pairs of the first and second barrier walls may be arranged on substantially the same planes.

According to an aspect of the present disclosure, the nozzles are not arranged to directly face the patterning slit sheet.

According to various embodiments, the nozzle unit may include a plurality of first nozzles inclined at a first angle with respect to the patterning slit sheet, and a plurality of second nozzles arranged to be inclined at a second angle with respect to the patterning slit sheet.

According to various embodiments, the first and second nozzles may be alternately disposed on the nozzle unit.

According to various embodiments, the first nozzles and the second nozzles may be symmetrical to each other, with respect to the first direction and a line perpendicular to the patterning slits arranged in the first direction.

According to an aspect of the present disclosure, there is provided a method of manufacturing an organic light-emitting display apparatus using a thin film deposition apparatus according to the present exemplary embodiments, the method comprising: disposing one of the above deposition apparatuses adjacent to a substrate, such that the patterning slit sheet faces, and is spaced apart from the substrate; vaporizing the deposition material in the crucible, using the heater; patterning the substrate by ejecting the vaporized deposition material through the nozzles and the patterning slit sheet, onto the substrate; and collecting the vaporized deposition material, in the collection unit.

According to various embodiments, the deposition process may be performed while the thin film deposition apparatus and the substrate are moved relative to each other, in a direction perpendicular to the first direction.

According to various embodiments, the collecting comprises closing the first valve and opening the second valve, so that the vaporized deposition material is stored in the deposition material recovery unit.

According to various embodiments, the deposition material stored in the deposition material recovery unit may be recovered and reused.

Additional aspects and/or advantages of the disclosure will be set forth in part in the description which follows and, in part, will be obvious from the description, or may be learned by practice of the disclosure.

### BRIEF DESCRIPTION OF THE DRAWINGS

These and/or other aspects and advantages of the disclosure will become apparent and more readily appreciated from the following description of the embodiments, taken in conjunction with the accompanying drawings of which:

FIG. 1 is a schematic cross-sectional view of a deposition source, according to an exemplary embodiment of the present disclosure;

FIG. 2 is a schematic perspective view of a thin film deposition apparatus, according to an exemplary embodiment of the present disclosure.

FIG. 3 is a schematic side view of the thin film deposition apparatus of FIG. 2;

FIG. 4 is a schematic plan view of the thin film deposition apparatus of FIG. 2;

FIG. 5 is a schematic perspective view of a thin film deposition apparatus, according to an exemplary embodiment of the present disclosure.

FIG. 6 is a schematic perspective view of a thin film deposition apparatus, according to an exemplary embodiment of the present disclosure; and

FIG. 7 is a schematic cross-sectional view of an organic light-emitting display apparatus that is manufactured using the thin film deposition apparatus of FIG. 2, 5, or 6, according to an exemplary embodiment of the present disclosure.

### DETAILED DESCRIPTION

Reference will now be made in detail to the exemplary embodiments of the present disclosure, examples of which are illustrated in the accompanying drawings, wherein like reference numerals refer to the like elements throughout. The exemplary embodiments are described below, in order to explain the aspects of the present disclosure, by referring to the figures.

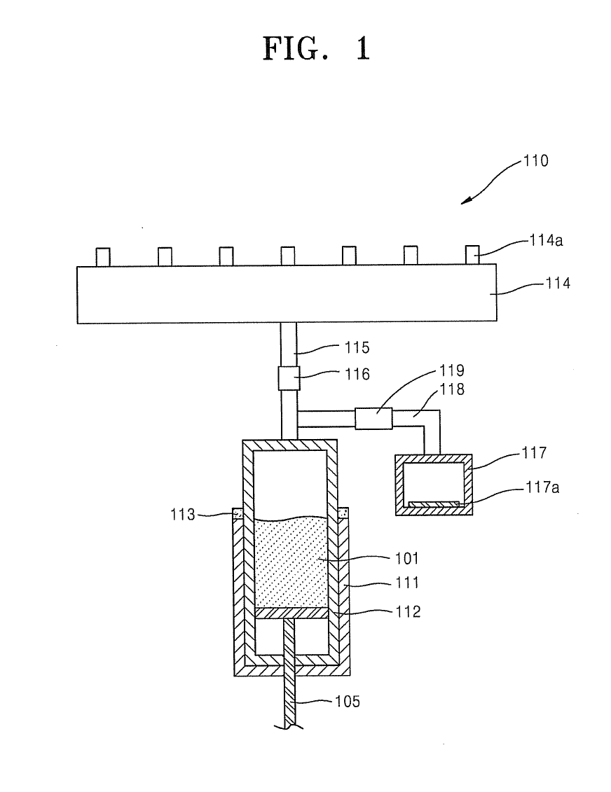

FIG. 1 is a schematic cross-sectional view of a deposition source 110, according to an exemplary embodiment of the present disclosure. Referring to FIG. 1, the deposition source 110 includes a crucible 112, a heater 113, a nozzle unit 114, a first connector 115, a first valve 116, a second connector 118, a second valve 119, and a deposition material recovery unit 117.

A deposition material 101 is filled in the crucible 112. The heater 113 is disposed around an outer circumference of the crucible 112. The heater 113 heats the crucible 112, to vaporize the deposition material 101.

The deposition source 110 may further include a supply member 105 connected to the crucible 112. In detail, as the deposition material 101 is vaporized, the supply member 105 is moved to push the deposition material 101 upwards. To this end, a predetermined portion of the supply member 105 is disposed beneath the deposition material 101, in the crucible 112.

A cooling member 111 is disposed beneath the heater 113 to surround the outer circumference of the crucible 112. The cooling member 111 prevents materials of the deposition material 101 filled in the crucible 112, which are distant from the heater 113 and are not conducive to a deposition process, from being denatured by heat.

A nozzle unit 114 is disposed at a side of the crucible 112. The nozzle unit 114 includes a plurality of nozzles 114a arranged in one direction. The nozzle unit 114 faces a target (not shown) on which the deposition material 101 is to be deposited. The deposition material 101 that has been heated in the crucible 112 and vaporized passes to the nozzle unit 114 and is then ejected by the nozzles 114a towards the target. However, aspects of the present disclosure are not limited thereto. For example, the deposition source 110 may also include one nozzle 114a.

The first connector 115 provides a fluid communication between the crucible 112 and the nozzle unit 114. The deposition material 101 is vaporized in the crucible 112 and is then moved to the nozzle unit 114, via the first connector 115.

The first valve 116 is formed on/in the first connector 115. The first valve 116 is opened or closed, so as to control the flow of the vaporized deposition material 101 through the first connector 115, to the nozzle unit 114.

Deposition is not performed, during the alignment of the deposition source 110 and the target. The first valve 116 is closed during the alignment, so as to prevent the deposition material 101 from leaking from the nozzle unit 114, when deposition should not be performed. In other words, the first valve 116 is open, when deposition is performed, and the first valve 116 is closed, when deposition is not being performed, so as to prevent waste of the deposition material 101.

A deposition material recovery unit 117 is connected to the first connector 115. The deposition material recovery unit 117 recovers the deposition material 101, when the first valve 116 is closed. To this end, the deposition material recovery unit 117 includes a removable recovery plate 117a. The vaporized deposition material 101 is stacked (collected) on the recovery plate 117a. The recovery plate 117a may be detached from the deposition material recovery unit 117, so as to allow deposition material to be easily reused.

In detail, the second connector 118 provides a fluid communication between the deposition material recovery unit 117 and the first connector 115. The second connector 118 is connected to the first connector 115, between the crucible 112 and the first valve 116.

The second valve 119 is disposed on the second connector 118. The second valve 119 is opened or closed, so as to selectively control the transfer of the deposition material 101, from the crucible 112 to the deposition material recovery unit 117. In other words, when the second valve 119 is closed and the first valve 116 is open, the deposition material 101 may be substantially deposited on the target, via the deposition process.

As described above, when the deposition source 110 is used, the first valve 116 is closed to prevent waste of the deposition material 101, when deposition is not substantially performed on the target. This is because the heated deposition material 101 in the crucible 112 continues to be vaporized, even when deposition is not being performed. For this reason, the first valve 116 is closed when deposition is not being performed.

The vaporized deposition material 101 may be denatured when held in a confined space, i.e., a space between the first valve 116, the inner circumference of the crucible 112, and the inside of the first connector 115, or in an area adjacent to the first valve 116. In particular, pressure in the space may be increased when the first valve 116 is closed and the crucible is at an elevated temperature, which may result in the denaturation of the deposition material 101. The denaturation of the deposition material 101 degrades the characteristics of the deposition material 101 and thus, causes the characteristics of a deposited layer to be degraded.

However, in the deposition source 110, the vaporized deposition material 101 is recovered by the deposition material recovery unit 117, when the first valve 116 is closed. Therefore, the denaturation of the deposition material 101 may be prevented.

An operation of the deposition source 110 will be described in detail. First, the first valve 116 is opened, so that the deposition material 101 is moved to the nozzle unit 114, when the deposition process is performed on the target. In this case, the second valve 119 is closed, so that the deposition material 101 may be efficiently transferred to the target. When deposition is not substantially performed on the target, such as during the alignment of the deposition source 110 and the target, the first valve 116 is closed, and the second valve 118 is opened, so that the vaporized deposition material 101 may be stacked on the recovery plate 117a of the deposition material recovery unit 117. The deposition material 101 on the recovery plate 117a may be returned to the crucible 112, through an additional separation process (117a).

Thus, the deposition material 101 may be efficiently stored. The deposition process may be efficiently performed, by reusing the deposition material 101, and the characteristics of a deposited layer may be improved.

The deposition source 110 may be used in a thin film deposition apparatus. Embodiments of the thin film deposition apparatus using the deposition source 110 will be described below. However, aspects of the present disclosure are not limited thereto, and the deposition source 110 of FIG. 1 may be used in various other thin film deposition apparatuses.

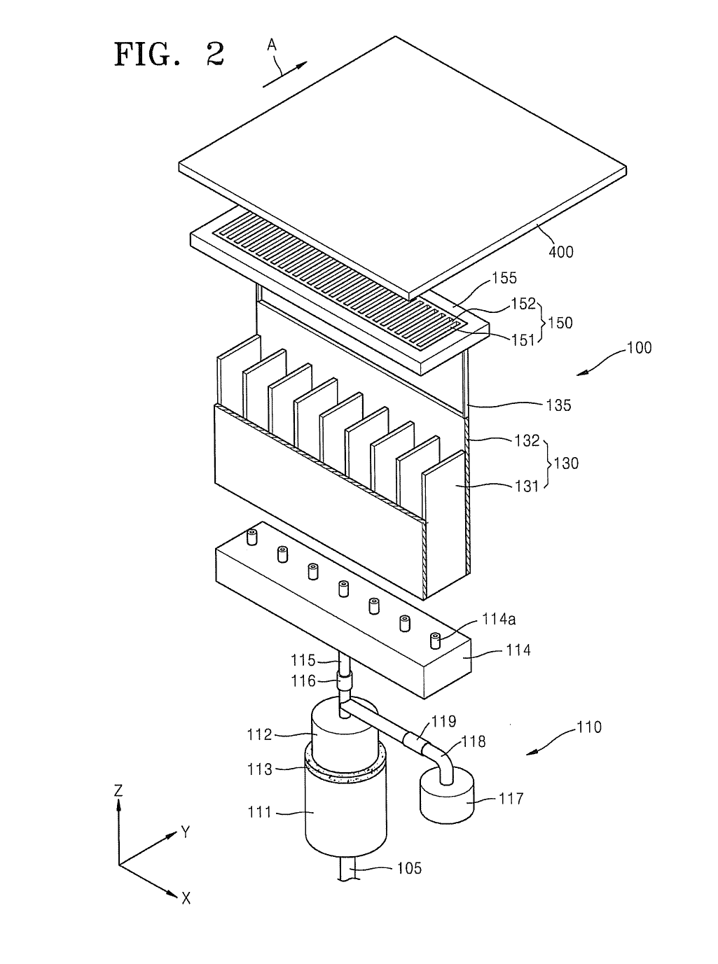

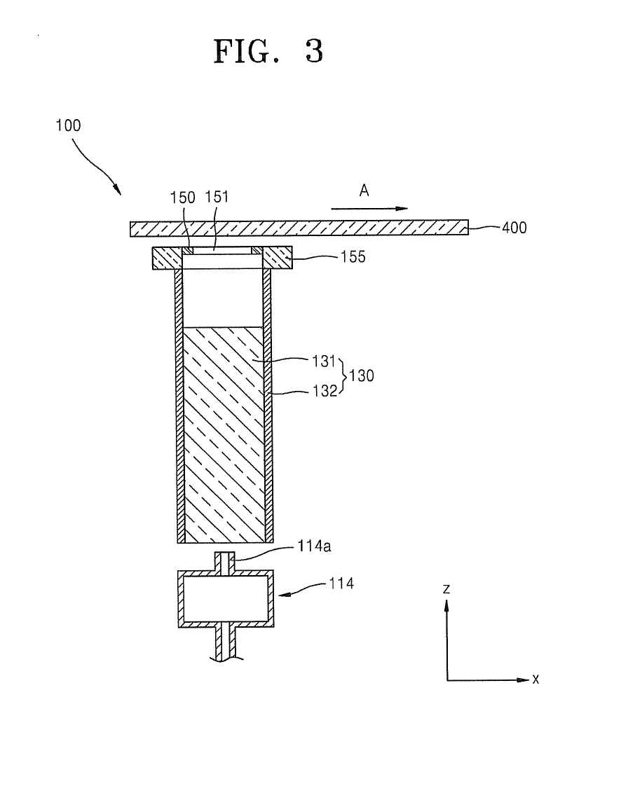

FIG. 2 is a schematic perspective view of a thin film deposition apparatus 100, according to an exemplary embodiment of the present disclosure, FIG. 3 is a schematic side view of the thin film deposition apparatus 100, and FIG. 3 is a schematic plan view of the thin film deposition apparatus 100 of FIG. 2. Although not illustrated in FIGS. 2, 3, and 4 for convenience of explanation, all the components of the thin film deposition apparatus 100 may be disposed within a chamber. The chamber is maintained at an appropriate vacuum, in order to allow a deposition material to move in a substantially straight line, through the thin film deposition apparatus 100.

The thin film deposition apparatus 100 includes a deposition source 110, a barrier wall assembly 130, and a patterning slit sheet 150. A substrate 400, upon which a deposition material (not shown) is deposited, is also shown. The thin film deposition apparatus 100 faces the substrate 400. According to other aspects of the present disclosure, the thin film deposition apparatus 100 may include additional and/or different components, such as in the examples described below.

The deposition source 110 includes a crucible 112 that holds the deposition material, and a nozzle unit 114 through which the deposition material is discharged. The nozzle unit 114 includes a plurality of nozzles 114a. The nozzles 114a are disposed facing the substrate 400. In particular, the nozzles 114a may protrude from a surface of the nozzle unit 114, so as to directly face the patterning slit sheet 150. In other words, the nozzles 114a are arranged to eject the deposition material directly towards the patterning slit sheet 114. The nozzles 114a are arranged along a first direction, (X-axis direction in FIG. 2). The nozzles 114a may be arranged at equal intervals. The deposition source 110 is the same as the deposition source 110 of FIG. 1, and thus, a detailed description thereof will not be provided here.

The substrate 400 may be any suitable substrate for a flat panel display. A large substrate, such as a mother glass for manufacturing a plurality of flat panel displays, may be used as the substrate 400. Other substrates may also be employed.

The patterning slit sheet 150 is disposed facing the nozzle unit 114 and includes a plurality of patterning slits 151 arranged in the first direction, i.e., the X-axis direction. In detail, the patterning slits 151 are disposed between patterning ribs 152. The thin film deposition apparatus 100 may further include a frame 155 to support the patterning slit sheet 150, as illustrated in FIG. 2. The frame 155 may be formed in a lattice shape, similar to a window frame. The patterning slit sheet 150 is held inside the frame 155. Each of the patterning slits 151 extends in the Y-axis direction in FIG. 2, which intersects the first direction at a substantially right angle.

The deposition material is vaporized in the deposition source 110 and passes through the nozzle unit 114. The deposition material then passes through the patterning slits 151, before being deposited on the substrate 400.

The patterning slit sheet 150 may be formed from a metal thin film. The patterning slit sheet 150 is fixed to the frame 150, such that a tensile force is exerted thereon. The patterning slits 151 may be formed by etching a striped pattern into the patterning slit sheet 150. The total number of patterning slits 151 may be greater than the total number of the nozzles 114.

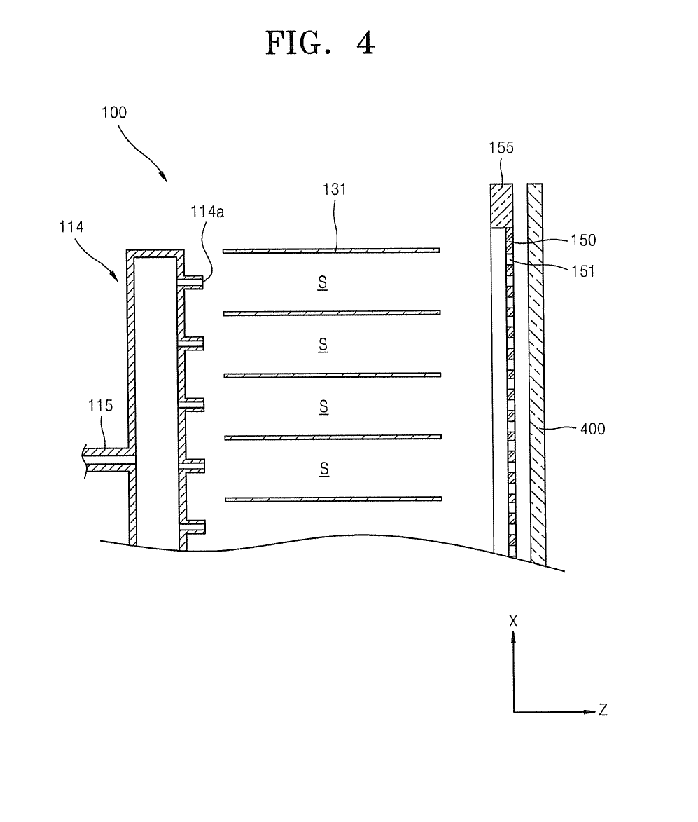

The barrier wall assembly 130 includes a plurality of barrier walls 131 that are disposed between the deposition source 110 and the patterning slit sheet 150. The barrier walls 131 are spaced apart in the first direction. The barrier walls 131 divide the space between the nozzle unit 114 and the patterning slit sheet 150 into a plurality of sub-deposition spaces S. The sub-deposition spaces S respectively correspond to the nozzles 114a, in a 1:1 ratio, as illustrated in FIG. 4. The barrier wall assembly 130 may further include a barrier wall frame 132 that constitutes outer walls of the barrier wall assembly 130, as illustrated in FIG. 2.

The barrier walls 131 may extend in parallel planes that are spaced apart at equal intervals, in the X-axis direction. In addition, each of the barrier walls 131 may be arranged parallel to an YZ plane in FIG. 2, and may have a rectangular shape.

The barrier walls 131 may be disposed between adjacent nozzles 114a. In other words, each of the nozzles 114a may be disposed between two adjacent barrier walls 131. In particular, the nozzles 114a may be respectively located at the midpoint between each pair of adjacent barrier walls 131, as illustrated in FIG. 4. However, aspects of the present disclosure are not limited thereto, and different numbers of the nozzles 114a may be arranged between each pair of adjacent barrier walls 131.

As described above, since the barrier walls 131 form the sub-deposition spaces S, the deposition material discharged from each of the nozzles 114a is not mixed with the deposition material discharged through other ones of the nozzles 114a. The deposition material then passes through the patterning slits 151, so as to be deposited on the substrate 400 in a pattern. Thus, the barrier walls 131 guide the deposition material in substantially straight lines, in the Z-axis direction, through the thin film deposition apparatus 100.

As described above, the deposition material is forced to move in a substantially straight line through the thin film deposition apparatus 100, by installing the barrier walls 131, so that a smaller shadow zone may be formed on the substrate 400, as compared to a case where no barrier walls are installed. Thus, the thin film deposition apparatus 100 and the substrate 400 can be separated from each other, by a predetermined distance.

The barrier wall frame 132, which is disposed on opposing sides of the barrier walls 131, maintains the positions of the barrier walls 131. The barrier wall frame 132 guides the deposition material, which is discharged through one of the nozzles 114a, so as not to flow in the Y-axis direction.

The nozzle unit 114 and the barrier wall assembly 130 may be separated from each other, by a predetermined distance. This may prevent the heat of the deposition source 110 from being conducted to the barrier wall assembly 130. However, aspects of the present disclosure are not limited thereto. Thus, an appropriate heat insulator (not shown) may be included between the nozzle unit 114 and the barrier wall assembly 130. In this case, the nozzle unit 114 and the barrier wall assembly 130 may be bound together, with the heat insulator therebetween.

The barrier wall assembly 130 may be detachable from the thin film deposition apparatus 100. The deposition space is enclosed via the barrier wall assembly 130, so that the un-deposited deposition material is mostly deposited within the barrier wall assembly 130. Thus, when a large amount of the deposition material is deposited in the barrier wall assembly 130, such as after a long deposition process, the barrier wall assembly 130 may be detached from the thin film deposition apparatus 100 and then placed in a separate deposition material recycling apparatus, in order to recover the deposition material. Due to the structure of the thin film deposition apparatus 100, a reuse rate of the deposition material is increased, so that the deposition efficiency is improved. Thus, the manufacturing costs are reduced.

As described above, the total number of patterning slits 151 may be greater than the total number of nozzles 114a. In addition, there may be a greater number of patterning slits 151 than nozzles 114a disposed between two adjacent barrier walls 131. The number of patterning slits 151 may be equal to the number of deposition patterns to be formed on the substrate 400. Thus, a layer pattern corresponding to the patterning slits 151 may be deposited on the substrate 400, without using an additional mask.

In addition, the barrier wall assembly 130 and the patterning slit sheet 150 may be separated from each other, by a predetermined distance. Alternatively, the barrier wall assembly 130 and the patterning slit sheet 150 may be connected by a connection member 135. In detail, the temperature of the barrier wall assembly 130 may increase to 100° C., or higher, due to heat from the deposition source 110. Thus, in order to prevent the heat of the barrier wall assembly 130 from being conducted to the patterning slit sheet 150, the barrier wall assembly 130 and the patterning slit sheet 150 may be separated from each other.

In order to deposit the deposition material that has been discharged from the deposition source 110 and passed through the nozzle unit 114 and the patterning slit sheet 151, onto the substrate 400 in a desired pattern, a chamber (not shown) should generally be maintained in a high-vacuum state. The deposition material moves in a random direction immediately after being discharged from the nozzles 114, but is then guided by the barrier walls 131 in the Z-axis direction. The deposition material discharged in undesired directions may be adhered to surfaces of the barrier wall assembly 130, i.e., the barrier walls 131, and may be less likely to collide with the correctly discharged deposition material. Thus, the deposition material is forced to move in a substantially straight line, through the thin film deposition apparatus 100.

The deposition may be continuously performed, while the thin film deposition apparatus 100 and the substrate 400 are moved relative to each other, in the Y-axis direction. In other words, deposition is performed in a scanning manner, while the substrate 400 is moved in the direction of arrow A in FIG. 2. Alternatively, the thin film deposition apparatus 100 may be moved in the Y-axis direction, with the substrate 400 being fixed. Thus, in the thin film deposition apparatus 100, the patterning slit sheet 150 may be significantly smaller than a fine metal mask (FMM) used in a conventional deposition method.

In order to perform deposition while the thin film deposition apparatus 100 and the substrate 400 are moved relative to each other, as described above, the thin film deposition apparatus 100 and the substrate 400 may be separated from each other, by a predetermined distance. In addition, in order to prevent the formation of a relatively large shadow zone on the substrate 400, due to the non-uniformly deposited deposition material when the patterning slit sheet 150 and the substrate 400 are separated from each other, the barrier walls 131 are arranged between the nozzle unit 114 and the patterning slit sheet 150, to force the deposition material to move in a substantially straight line through the thin film deposition apparatus 100. Thus, the size of the shadow zone formed on the substrate 400 is sharply reduced.

In detail, in a conventional deposition method using an FMM, deposition is performed with the FMM in close contact with a substrate, in order to prevent the formation of a shadow zone on the substrate. However, such contact may cause defects, such as scratches on patterns formed on the substrate. In addition, in the conventional deposition method, the size of the mask should be the same as the size of the substrate, since the mask cannot be moved relative to the substrate. Thus, large masks are needed to form large display devices. However, it is not easy to manufacture such a large mask.

In order to overcome this and/or other problems, the patterning slit sheet 150 is separated from the substrate 400. This may be facilitated by installing the barrier walls 131, to reduce the size of the shadow zone formed on the substrate 400.

As described above, when the patterning slit sheet 150 is manufactured to be smaller than the substrate 400, the pattern slit sheet 150 may be moved relative to the substrate 400, during deposition. Thus, it is not necessary to manufacture a large FMM, as is used in the conventional deposition method. In addition, since the substrate 400 and the patterning slit sheet 150 are separated from each other, defects caused due to contact therebetween may be prevented. In addition, since it is unnecessary to contact the substrate 400 with the patterning slit sheet 150 during a deposition process, the manufacturing speed may be improved.

When deposition is performed on the substrate 400, the first valve 116 is open, and the second valve 119 is closed. When deposition is not substantially performed on the substrate 400, the first valve 116 is closed, and the second valve 119 is open. Thus, the vaporized deposition material is stacked on the recovery plate 117a of the deposition material recovery unit 117, when deposition is not being performed. Thus, waste and degradation of the deposition material are prevented. The deposition material that has been stacked on the recovery plate 117a may be reused, through an additional process.

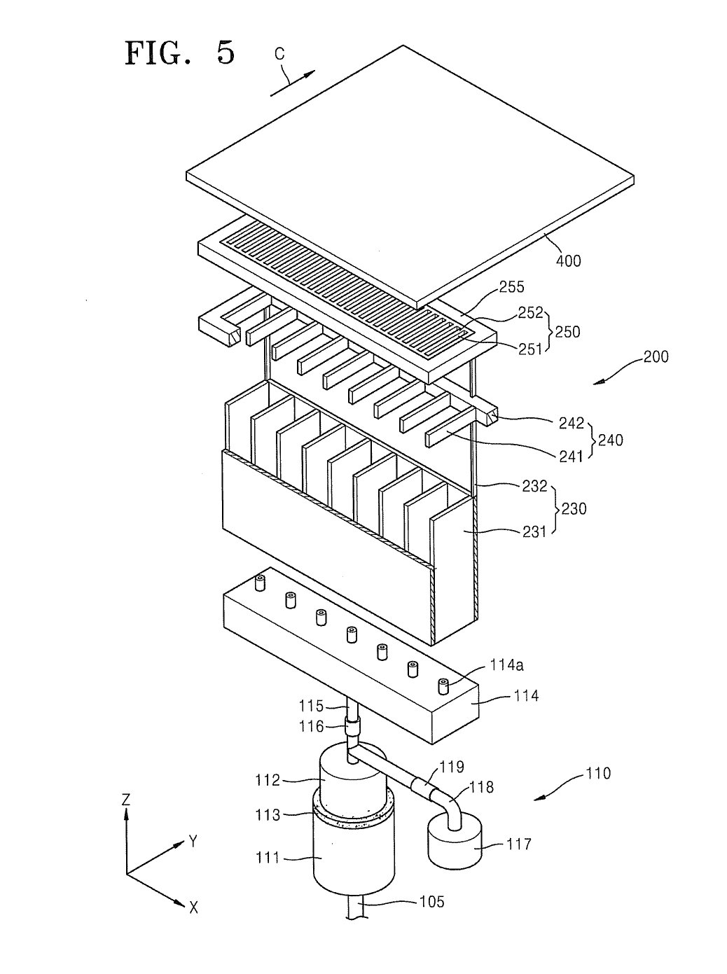

FIG. 5 is a schematic perspective view of a thin film deposition apparatus 200, according to an exemplary embodiment of the present disclosure. Referring to FIG. 5, the thin film deposition apparatus 200 includes a deposition source 110, a first barrier wall assembly 230, a second barrier wall assembly 240, and a patterning slit sheet 250 including patterning slits 251.

Although not illustrated in FIG. 5 for convenience of explanation, all the components of the thin film deposition apparatus 200 may be disposed within a chamber (not shown), as recited above. A substrate 400, on which a deposition material (not shown) is to be deposited, is disposed in the chamber. The deposition source 110 that heats the deposition material is disposed in an opposite side of the chamber with respect to the side in which the substrate 400 is disposed.

The deposition source 110, patterning slit sheet 250, and first barrier wall assembly 230, are similar to the corresponding elements described above. Thus, detailed descriptions thereof will not be repeated.

The second barrier wall assembly 240 is disposed between the first barrier wall assembly 230 and the patterning slit sheet 250. The second barrier wall assembly 240 includes a plurality of second barrier walls 241, and a second barrier wall frame 242 that constitutes an outer wall disposed around the second barrier walls 241.

The second barrier walls 241 may be arranged parallel to each other, at equal intervals in the X-axis direction. In addition, each of the second barrier walls 241 may be formed to extend in the YZ planes in FIG. 5, i.e., perpendicular to the X-axis direction.

The first barrier walls 231 and second barrier walls 241 partition the space between a nozzle unit 114 and the patterning slit sheet 250. In detail, sub-deposition spaces that respectively correspond to nozzles 114a are at least partially formed by the first and second barrier walls 231, 241.

The second barrier walls 241 may be disposed to correspond to the first barrier walls 231. In other words, corresponding pairs of the first and second barrier walls 231, 241 may be disposed in the same plane. The width of the first barrier walls 231 may be the same or different than the width of the second barrier walls 241, in the X-axis direction. In some aspects, the second barrier walls 241, which should be accurately aligned with the patterning slit sheet 251, may be relatively thin, whereas the first barrier walls 231, which do not need to be precisely aligned with the patterning slit sheet 251, may be relatively thick. This makes it easier to manufacture the thin film deposition apparatus 200.

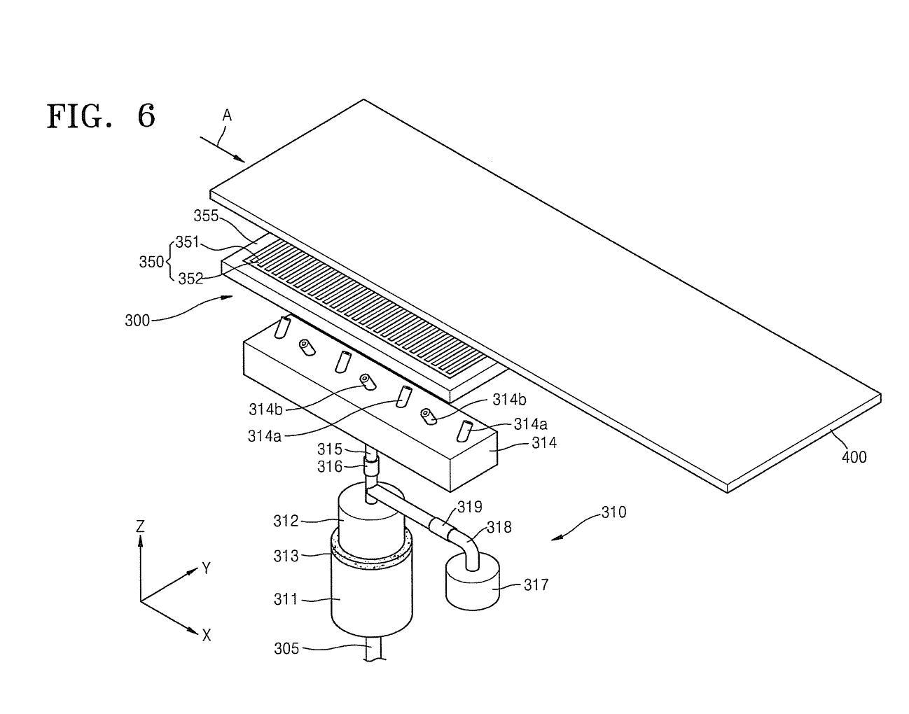

FIG. 6 is a schematic perspective view of a thin film deposition apparatus 300, according to an exemplary embodiment of the present disclosure. The thin film deposition apparatus 300 includes a deposition source 310 and a patterning slit sheet 350. The thin film deposition apparatus 300 is disposed to face a substrate 400, which is a target on which a deposition material (not shown) is to be deposited.

A deposition process is performed while the thin film deposition apparatus 300 and the substrate 400 are moved relative to each other, along a first direction (X-axis direction). In other words, the deposition process is performed while the thin film deposition apparatus 300 or the substrate 400 is moved in the direction of arrow A in FIG. 6.

Although a chamber is not illustrated in FIG. 6 for convenience of explanation, all the components of the thin film deposition apparatus 300 may be disposed within a chamber that is maintained at an appropriate degree of vacuum. The substrate 400, on which the deposition material is to be deposited, is disposed in the chamber. The deposition source 310 and the substrate 400 are disposed on opposite sides of the chamber.

The patterning slit sheet 350 includes a plurality of patterning slits 351. The patterning slit sheet 350 is similar to the patterning slit sheet 150 of FIG. 2, and thus, a detailed description thereof will not be repeated.

A deposition process is performed while the thin film deposition apparatus 300 and the substrate 400 are moved relative to each other, in a first direction A (X-axis direction). In detail, the thin film deposition apparatus 300 or the substrate 400 is moved in the X-axis direction, in which nozzles of a nozzle unit 314 are arranged. In this case, the direction in which the deposition material is emitted from the nozzles of a nozzle unit 314 need not be strictly controlled. Thus, the thin film deposition apparatus 300 does not include barrier wall assemblies.

The deposition source 310 includes a crucible 312, a heater 313, the nozzle unit 314, a first connector 315, a first valve 316, a second connector 318, a second valve 319, and a deposition material recovery unit 317. The nozzle unit 314 includes a plurality of nozzles, i.e., a plurality of first nozzles 314a and a plurality of second nozzles 314b.

Only the nozzle unit 314 of the deposition source 310 is different from the structure of the deposition source 110 of FIG. 1. Thus, for convenience of explanation, only the nozzle unit 314 will be described below.

Each of the first nozzles 314a and each of the second nozzles 314b are inclined at predetermined angles, with respect to the surface of the nozzle unit 314 from which the nozzles 314a, 314b extend. In other words, each of the first nozzles 314a and each of the second nozzles 314b are inclined at predetermined angles from an YZ plane, in the Z-axis direction. Specifically, the first and second nozzles 314a, 314b can be referred to as not directly facing the patterning slit sheet 350, such that the first and second nozzles 314a, 314b do not extend from the surface of the nozzle unit 314 at a right angle.

In this case, each of the first nozzles 314a may all be inclined at a first angle, and each of the second nozzles 314b may be inclined at a second angle, with respect to the surface of the nozzle unit 314. The first nozzles 314a and the second nozzles 314b may be symmetrical to each other with respect to the Z-axis direction. The first and second nozzles 314a, 314b are alternately disposed on the surface of the nozzle unit 314.

Deposition is performed while the thin film deposition apparatus 300 is moved in the X-axis direction, which is the same direction in which the first and second nozzles 314a, 314b are arranged. For this reason, deposition characteristics of the center and a circumference of the nozzle unit 314, in the X-axis direction, may vary. In detail, as the thin film deposition apparatus 300 is farther from the center of the nozzle unit 314 in the Y-axis direction, based on the X-axis direction, the thickness of a deposited layer may be reduced. The angles of the first nozzles 314a and the second nozzles 314b allow for the formation of a deposited layer having a uniform thickness.

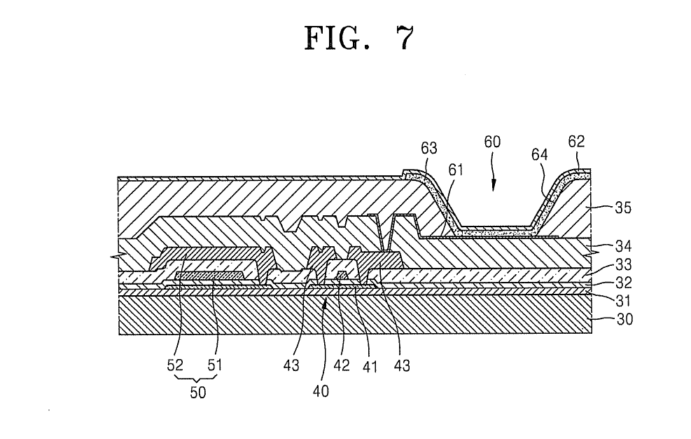

FIG. 7 is a schematic cross-sectional view of an active matrix organic light-emitting display apparatus that is manufactured using the thin film deposition apparatus 100, 200, or 300, according to an exemplary embodiment of the present disclosure. Referring to FIG. 7, the active matrix organic light-emitting display apparatus includes a substrate 30 formed of a transparent material, for example, glass, plastic, or metal. An insulating layer 31, such as a buffer layer, is formed on an entire surface of the substrate 30.

A thin film transistor (TFT) 40, a capacitor 50, and an organic light-emitting device 60 are disposed on the insulating layer 31, as illustrated in FIG. 7. A semiconductor active layer 41 is formed on an upper surface of the insulating layer 31, in a predetermined pattern. A gate insulating layer 32 is formed to cover the semiconductor active layer 41. The semiconductor active layer 41 may include a p-type or n-type semiconductor material.

A gate electrode 42 of the TFT 40 is formed in a region of the gate insulating layer 32 corresponding to the semiconductor active layer 41. An interlayer insulating layer 33 is formed to cover the gate electrode 42. The interlayer insulating layer 33 and the gate insulating layer 32 are etched by, for example, dry etching, to form a contact hole exposing parts of the semiconductor active layer 41.

A source/drain electrode 43 is formed on the interlayer insulating layer 33, so as to contact the semiconductor active layer 41 through the contact hole. A passivation layer 34 is formed to cover the source/drain electrode 43, and is etched to expose a part of the drain electrode 43 via an etching process. An insulating layer (not shown) may be further formed on the passivation layer 34, so as to planarize the passivation layer 34.

The organic light-emitting device 60 displays predetermined image information, by emitting red, green, or blue light according to current flow. The organic light-emitting device 60 includes a first electrode 61, an organic light-emitting layer 63, and a second electrode 62. The first electrode 61 is formed on the passivation layer 34. The first electrode 61 is electrically connected to the drain electrode 43 of the TFT 40.

A pixel defining layer 35 is formed to cover the first electrode 61. An opening 64 is formed in the pixel defining layer 35. The organic light-emitting layer 63 is formed in a region defined by the opening 64. The second electrode 62 is formed on the organic light-emitting layer 63.

The pixel defining layer 35, which defines individual pixels, is formed of an organic material. The pixel defining layer 35 also planarizes the surface of a region of the substrate 30 where the first electrode 61 is formed, and in particular, the surface of the passivation layer 34. The first electrode 61 and the second electrode 62 are insulated from each other, and respectively apply voltages of opposite polarities to the organic light-emitting layer 63, including the emission layer, to induce light emission.

The organic light-emitting layer 63 may be formed of a low-molecular weight organic material or a high-molecular weight organic material. When a low-molecular weight organic material is used, a single or multi-layer structure, including at least one selected from the group consisting of a hole injection layer (HIL), a hole transport layer (HTL), an electron transport layer (ETL), an electron injection layer (EIL), etc. is disposed with the organic light-emitting layer 63. Examples of available organic materials may include copper phthalocyanine (CuPc), N,N′-di(naphthalene-1-yl)-N,N′-diphenyl-benzidine (NPB), tris-8-hydroxyquinoline aluminum (Alq3), etc. Such a low-molecular weight organic material may be deposited by vacuum deposition, using a thin film deposition apparatus including the deposition source of FIG. 1, or one of the thin film deposition apparatuses of FIGS. 2 through 6.

Once the opening 64 has been formed in the pixel defining layer 35, the substrate 30 is transferred to a chamber. A target organic material is contained in a crucible of a deposition source and then is deposited on the substrate 30. After the organic light-emitting layer 63 is formed, the second electrode 62 may be formed by the same deposition method as used to form the organic light-emitting layer 63.

The first electrode 61 may operate as an anode, and the second electrode 62 may operate as a cathode. Alternatively, the first electrode 61 may operate as a cathode, and the second electrode 62 may operate as an anode. The first electrode 61 may be patterned to correspond to individual pixel regions, and the second electrode 62 may be formed to cover all the pixels.

The pixel electrode 61 may be formed as a transparent electrode or a reflective electrode. Such a transparent electrode may be formed of indium tin oxide (ITO), indium zinc oxide (IZO), zinc oxide (ZnO), or indium oxide (In₂O₃). Such a reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, or In₂O₃ on the reflective layer. The first electrode 61 may be formed by forming a layer by, for example, sputtering, and then patterning the layer by, for example, photolithography.

The second electrode 62 may also be formed as a transparent electrode or a reflective electrode. When the second electrode 62 is formed as a transparent electrode, the second electrode 62 operates as a cathode. To this end, such a transparent electrode may be formed by depositing a metal having a low work function, such as lithium (Li), calcium (Ca), lithium fluoride/calcium (LiF/Ca), lithium fluoride/aluminum (LiF/AI), aluminum (Al), silver (Ag), magnesium (Mg), or a compound thereof, on a surface of the organic light-emitting layer 63, and forming an auxiliary electrode layer or a bus electrode line thereon, using ITO, IZO, ZnO, In₂O₃, or the like. When the second electrode 62 is formed as a reflective electrode, the reflective layer may be formed by depositing Li, Ca, LiF/Ca, LiF/AI, Al, Ag, Mg, or a compound thereof. The second electrode 62 may be formed by using the same deposition method as used to form the organic light-emitting layer 63.

The thin film deposition apparatuses according to the exemplary embodiments of the present disclosure may be used to form a passive matrix organic light-emitting display apparatus and/or the active matrix organic light-emitting display apparatus. The thin film deposition apparatuses may be applied to form an organic layer and/or an inorganic layer of an organic TFT, and to form layers from various materials.

As described above, a deposition source, a thin film deposition apparatus using the deposition source, and a method of manufacturing an organic light-emitting display apparatus using the thin film deposition apparatus, according to aspects of the present disclosure, may prevent denaturation of deposition materials and may allow the deposition materials to be efficiently used.

Also, the deposition source, the thin film deposition apparatus using the deposition source, and the method of manufacturing an organic light-emitting display apparatus may easily improve the characteristics of deposited layers.

Although a few exemplary embodiments of the present disclosure have been shown and described, it would be appreciated by those skilled in the art that changes may be made in these exemplary embodiments, without departing from the principles and spirit of the present disclosure, the scope of which is defined in the claims and their equivalents.

What is claimed is:

1. A deposition source comprising:
a crucible to hold a deposition material;
a heater to vaporize the deposition material;
a nozzle unit to eject the deposition material;
a first connector to provide a fluid communication between the crucible and the nozzle unit;
a first valve to control movement of the deposition material through the first connector;
a deposition material recovery unit to recover the deposition material;
a second connector to provide a fluid communication between the first connector and the deposition material recovery unit; and
a second valve to control movement of the deposition material through the second connector.

2. The deposition source of claim 1, wherein:
the first valve is disposed in the first connector;
the second connector is attached to the first connector, between the crucible and the first valve; and
the second valve is disposed in the second connector.

3. The deposition source of claim 1, further comprising a cooling member surrounding the crucible.

4. The deposition source of claim 3, wherein the cooling member is separated from the heater.

5. The deposition source of claim 1, wherein the deposition material recovery unit comprises a detachable recovery plate, on which the deposition material is stacked.

6. The deposition source of claim 1, wherein the deposition material recovery unit recovers the deposition material when the first valve is closed and the second valve is open.

7. The deposition source of claim 1, wherein the nozzle unit comprises a plurality of nozzles to control the ejection of the deposition material.

8. A thin film deposition apparatus comprising:
a crucible to hold a deposition material;
a heater to heat the deposition material;
a nozzle unit to eject the deposition material, comprising a plurality of nozzles arranged in a first direction;
a first connector to provide a fluid communication between the crucible and the nozzle unit;
a first valve to control movement of the deposition material through the first connector;
a deposition material recovery unit to recover the deposition material;
a second connector to provide a fluid communication between the first connector and the deposition material recovery unit;
a second valve to control movement of the deposition material through the second connector;
a patterning slit sheet disposed facing the nozzle unit, comprising patterning slits arranged in the first direction; and
a barrier wall assembly comprising barrier walls disposed between the nozzle unit and the patterning slit sheet and spaced apart in the first direction, so as to form sub-deposition spaces between the nozzle unit and the patterning slit sheet.

9. The thin film deposition apparatus of claim 8, wherein:
the first valve is disposed in the first connector;
the second connector is connected to the first connector, between the crucible and the first valve; and
the second valve is disposed in the second connector.

10. The thin film deposition apparatus of claim 8, further comprising a cooling member surrounding the crucible.

11. The thin film deposition apparatus of claim 10, wherein the cooling member is separated from the heater.

12. The thin film deposition apparatus of claim 8, wherein the deposition material recovery unit comprises a detachable recovery plate, upon which the deposition material is collected.

13. The thin film deposition apparatus of claim 8, wherein the deposition material recovery unit recovers the deposition material, when the first valve is closed and the second valve is open.

14. The thin film deposition apparatus of claim 8, wherein the barrier walls are separated from the patterning slit sheet.

15. The thin film deposition apparatus of claim 8, wherein the barrier walls are spaced apart at equal intervals.

16. The thin film deposition apparatus of claim 8, wherein the deposition source and the barrier wall assembly are separated from each other.

17. The thin film deposition apparatus of claim 8, wherein the barrier wall assembly comprises:
a first barrier wall assembly comprising first barrier walls; and
a second barrier wall assembly comprising second barrier walls connected to the first barrier walls.

18. The thin film deposition apparatus of claim 17, wherein each of the first barrier walls and each of the second barrier walls extend in a second direction that is substantially perpendicular to the first direction, in order to form sub-deposition spaces between the nozzle unit and the patterning slit sheet.

19. The thin film deposition apparatus of claim 17, wherein the apparatus comprises equal numbers of the first and second barrier walls.

20. The thin film deposition apparatus of claim 19, wherein corresponding pairs of the first and second barrier walls are arranged in substantially the same planes.

21. A thin film deposition apparatus comprising:
a crucible to hold a deposition material;
a heater to heat the deposition material;
a nozzle unit to eject the deposition material, comprising nozzles arranged in a first direction;
a first connector to provide a fluid communication between the crucible and the nozzle unit;
a first valve to control the movement of the deposition material through the first connector;
a deposition material recovery unit to recover the deposition material;
a second connector to provide a fluid communication between the deposition material recovery unit and the first connector;
a second valve to control the movement of the deposition material through the second connector; and
a patterning slit sheet disposed facing the nozzle unit, comprising patterning slits arranged in the first direction,
wherein the nozzles do not directly face the patterning slit sheet.

22. The thin film deposition apparatus of claim 21, wherein:
the first valve is disposed in the first connector;
the second connector is connected to the first connector, between the crucible and the first valve; and
the second valve is disposed in the second connector.

23. The thin film deposition apparatus of claim 21, further comprising a cooling member surrounding the crucible.

24. The thin film deposition apparatus of claim 23, wherein the cooling member is separated from the heater.

25. The thin film deposition apparatus of claim 21, wherein the deposition material recovery unit comprises a detachable recovery plate upon which the deposition material is collected.

26. The thin film deposition apparatus of claim 21, wherein the deposition material recovery unit recovers the deposition material when the first valve is closed and the second valve is open.

27. The thin film deposition apparatus of claim 21, wherein the nozzles each face one of two different directions, with respect to a surface of the nozzle unit from which the nozzles extend.

28. The thin film deposition apparatus of claim 21, wherein adjacent ones of the nozzles face different directions.

29. The thin film deposition apparatus of claim 27, wherein the two different directions are symmetrical to each other, with respect to the surface of the nozzle unit.

30. A method of manufacturing an organic light-emitting display apparatus using the thin film deposition apparatus of claim 8, the method comprising:
disposing a substrate adjacent to, and spaced apart from, the patterning slit sheet;
vaporizing the deposition material in the crucible, using the heater;
patterning the substrate by ejecting the vaporized deposition material from the nozzles, through the patterning slit sheet, onto the substrate; and
collecting the vaporized deposition material, in the deposition material recovery unit.

31. The method of claim 30, wherein the patterning comprises moving the substrate relative to the thin film deposition apparatus, in the first direction.

32. The method of claim 30, wherein the collecting comprises closing the first valve and opening the second valve, so that the vaporized deposition material is collected in the deposition material recovery unit.

33. The method of claim 32, further comprising reusing the collected deposition material.

34. A method of manufacturing an organic light-emitting display apparatus using the thin film deposition apparatus of claim 21, the method comprising:
disposing a substrate adjacent to, and spaced apart from, the patterning slit sheet;
vaporizing the deposition material in the crucible, using the heater;
patterning the substrate by ejecting the vaporized deposition material from the nozzles, through the patterning slit sheet, and onto the substrate; and
collecting the vaporized deposition material, in the deposition recovery unit.

35. The method of claim 34, wherein the patterning comprises moving the substrate relative to the thin film deposition apparatus, in the first direction.

36. The method of claim 34, wherein the collecting comprises closing the first valve and opening the second valve, so that the vaporized deposition material is collected in the deposition material recovery unit.

37. The method of claim 36, further comprising reusing the collected deposition material.
